(19) United States
(12) Patent Application Publication
(10) Pub. No.: US 2019/0206753 A1
(43) Pub. Date: Jul. 4, 2019

(54) BICONTINUOUS POROUS CERAMIC COMPOSITE FOR SEMICONDUCTOR PACKAGE APPLICATIONS

(71) Applicant: Intel Corporation, Santa Clara, CA (US)

(72) Inventors: Taylor GAINES, Chandler, AZ (US); Mohit MAMODIA, Chandler, AZ (US); Paul START, Chandler, AZ (US); Ken HACKENBERG, Plano, TX (US)

(21) Appl. No.: 15/859,483

(22) Filed: Dec. 30, 2017

(51) Int. Cl. H01L 23/31; H01L 23/00; H01L 23/495; H01L 23/29; H01L 25/07

(52) U.S. Cl. CPC H01L 23/3114; H01L 23/562; H01L 25/074; H01L 23/291; H01L 23/49506

(57) ABSTRACT

Embodiments include semiconductor packages and a method of forming the semiconductor packages. A semiconductor package including a die on a substrate, where the die has a front side surface electrically coupled to the substrate and a backside surface that is opposite from the front side surface. The semiconductor package also has a bicontinuous ceramic composite (BCC) stiffener on the backside surface of the die. The BCC stiffener may include one or more materials, including porous ceramics, polymeric resins, and metals. The BCC stiffener may be directly coupled to the backside surface of the die without an adhesive layer. The BCC stiffener may be disposed on the die to reduce warpage based on the substrate and die. The semiconductor package may have the BCC stiffener formed with the one or more materials using a polymeric resin in a liquid state process and a resin pre-loaded in a ceramic process.

### FIELD

Embodiments relate to semiconductor devices. More particularly, the embodiments relate to packaging semiconductor devices with a bicontinuous porous ceramic/polymer composite implemented as a die backside stiffener and a picture frame stiffener.

### BACKGROUND

Packaging semiconductor devices, such as silicon wafers or dies, present several problems. One such problem is dies generate package warpage. Package warpage is typically generated as a result of a coefficient of thermal expansion (CTE) mismatch between the die and a substrate.

As an effective approach, packaging solutions typically use an epoxy mold compound and/or a stiffener comprising metallic materials (e.g., a stainless steel stiffner) to reduce package warpage. This presents additional problems for packaging solutions, especially for the current stiffener applications that include die backside stiffeners and picture frame stiffeners.

Epoxy mold compound typically achieves a low CTE by progressively adding fillers, which increases the overall viscosity and thus leads to various processing concerns. Composite materials, such as an epoxy mold compound, are commonly used in traditional semiconductor packaging industries to control the warpage of thin die packages/dies. As such, there are various processing concerns when using thin die packages with epoxy mold compounds, as these thin die packages are already predisposed to have high warpage both at room and reflow temperatures due to the CTE mismatch between the die and substrate and the low stiffness between the die and substrate.

Meanwhile, die backside stainless steel stiffeners have significant prohibitive challenges when applied on a singulated unit level. When the die backside stainless steel stiffeners are processed on a wafer level, the singulation of the wafer with stainless steel leads to burrs, respectively interfering with further downstream processing. Additionally, die backside stainless steel stiffener requires dispensing an adhesive layer between the die and the stiffener which leads to processing challenges, such as increased z-height, meeting tight keep-out-zones (KOZs), dispense optimization, and increased time and tooling/assembly costs. The required adhesive layer reduces the mitigation of the package warpage due to the weak mechanical coupling between the die and the die backside stainless steel stiffener, especially at high temperatures. Another problem with this stainless steel stiffener is that the adhesive layer acts as a thermal bottleneck (due to its low conductivity), which further limits the application of the die backside stainless steel stiffener to low-power semiconductor devices.

### BRIEF DESCRIPTION OF THE DRAWINGS

Embodiments described herein are illustrated by way of example and not limitation in the figures of the accompanying drawings, in which like references indicate similar features. Furthermore, some conventional details have been omitted so as not to obscure from the inventive concepts described herein.

FIG. 1 is a cross-sectional view of a semiconductor package with a bicontinuous ceramic composite (BCC) die backside stiffener, a die, and a substrate, according to one embodiment.

FIG. 2 is a cross-sectional view of a semiconductor package with a BCC picture frame stiffener, a die, and a substrate, according to one embodiment.

FIGS. 3A-3E are perspective view illustrations of a method of forming BCC stiffeners on a die and/or a substrate using a resin pre-loaded in ceramic technique, according to some embodiments.

FIGS. 4A-4E are perspective view illustrations of a method of forming BCC stiffeners on a die and/or a substrate using a polymeric resin in liquid state technique, according to some embodiments.

FIG. 5 is a perspective view of a tray having one or more shaped-openings used to form one or more BCC die backside stiffeners, according to one embodiment.

FIGS. 6A-6F are perspective view illustrations of a method of forming a BCC die backside stiffener on a wafer level, according to some embodiments.

FIG. 7 is a schematic block diagram illustrating a computer system that utilizes a device package (or a semiconductor package) with one or more BCC stiffeners, according to one embodiment.

### DETAILED DESCRIPTION

Described herein are systems that include a semiconductor package with a bicontinuous ceramic/polymer composite (BCC) (also referred to as a bicontinuous porous ceramic/polymer composite) implemented as a die backside stiffener and/or a picture frame stiffener, and methods of forming such semiconductor packages. Specifically, a semiconductor package (e.g., flip-chip packages) is described below and methods of forming such semiconductor package using BCC employed as a stiffener to provide thermal management and warpage control solutions both at room temperatures and reflow temperatures. The BCC stiffeners described herein can be employed as a picture frame stiffener surrounding the perimeter of the package and/or a die backside stiffener either at the wafer level or the unit level (after die attach).

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

For some embodiments, the BCC semiconductor packages described herein include BCCs used as stiffeners to enable solutions in semiconductor packaging applications (e.g., controlling/mitigating package level warpage). As used herein, a “BCC” refers to a highly porous ceramic material impregnated (or connected) with a curing polymeric resin which can be used in semiconductor packages as an improvement, for example, to epoxy mold compound and/or a stainless steel stiffener. As used herein, a “BCC semiconductor package” refers to a semiconductor package/substrate having a bicontinuous porous ceramic/polymer implemented as a die backside stiffener on a die and/or a picture frame stiffener surrounding a die.

According to some embodiments, the connected porous ceramic structure (and/or porous metal structure) helps to provide very high modulus, high strength, and ultra-low (but tunable) CTE. Additionally, after the curing process, these embodiments allow the polymeric resin to offer a continuous soft matrix while providing toughness to the brittle ceramic matrix. The polymeric resin further facilitates attachment/bonding to various substrates, including polymeric substrates, silicon die backsides, etc.

Embodiments of the BCC semiconductor package enable several advantages for packaging solutions as compared to typically used epoxy mold compound and stainless steel stiffeners. For example, as described below, these embodiments provide improvements in mechanical properties such as mitigating CTE mismatch, optimizing modulus, and controlling the properties of the combined materials. Unlike epoxy mold compounds, the BCCs rely on the connected network/matrix of the ceramic materials to control and optimize the overall CTE of the composite.

Meanwhile, in comparison with stainless steel stiffeners, the BCC described herein enhance the bonding mechanism/process in semiconductor packaging (e.g., dispensing/disposing an adhesive layer is not required). Accordingly, in these embodiments, the BCC semiconductor package can have (i) a polymer resin disposed directly on the porous ceramic after placement (where the capillary forces in the ceramic may limit the resin flow within the ceramic only), and/or (ii) a pre-polymerized epoxy resin already impregnated in the porous ceramic which can soften upon heating for bonding and can be successively cured later.

One additional advantage is that the BCC can be processed on a unit level but also on a wafer level to provide die backside stiffener. As such, the BCC can be applied at the wafer level and mitigate burrs during the singulation of the wafer which reduces downstream processing. For some embodiments, the BCC may be used as a thermal solution for some packages—in addition to a stiffener solution—by utilizing a thermally conductive porous ceramic (and/or metal), which may form a continuous thermal path between the die on the package and the environment above the ceramic composite.

The embodiments illustrated below use BCC which may include a bicontinuous composite of a porous ceramic, a curable polymeric resin, and/or a metal. One of the main advantages of a porous ceramic is offering a connected rigid matrix which has a reduced CTE and a high bending stiffness. Additionally, to overcome highly porous ceramic materials that can be brittle, the embodiments of the BCC impregnate the highly porous ceramic with a polymeric resin. As noted above, the polymeric resin facilitates the bonding of the BCC design (e.g., a BCC die backside stiffener) on various substrates.

According to some embodiments, the final properties of the BCC can be easily tailored and optimized by selecting, for example but not limited to, the type of porous ceramic, the pore size, the pore density, and the polymeric resins. For some of these embodiments, the BCC may include one or more different materials such as, but not limited to, polymeric resins, ceramics, and metals. These embodiments facilitate a wide range of bicontinuous composite materials that can be used to enhance the modulus of the stiffener. As such, the stiffener materials can be managed so that their modulus and CTE are optimized for warpage or stress reduction by controlling the final properties of the selected BCC.

For one embodiment, the BCC may include one or more polymeric resin materials such as, but not limited to, epoxies, acrylates, acrylics, nitriles, phenol formaldehydes, cross-linked polyurethanes and other engineering plastics, ultra-violet (UV) curable materials, thermally curable materials, moisture cure materials, combinations thereof, and/or any other natural and/or synthetic polymer materials. Additionally, for another embodiment, the BCC may include one or more ceramics materials such as, but not limited to, alumina, boron oxide, silica, silicon carbide, silicon nitride, zirconium oxide, titanium carbide, combinations thereof, and/or any other ceramic materials. For other embodiments, the BCC may also include one or more metallic materials such as, but not limited to, copper, aluminum, titanium, stainless steel, silver, gold, metal alloys (e.g., stainless steel), combinations thereof, and/or any metallic materials.

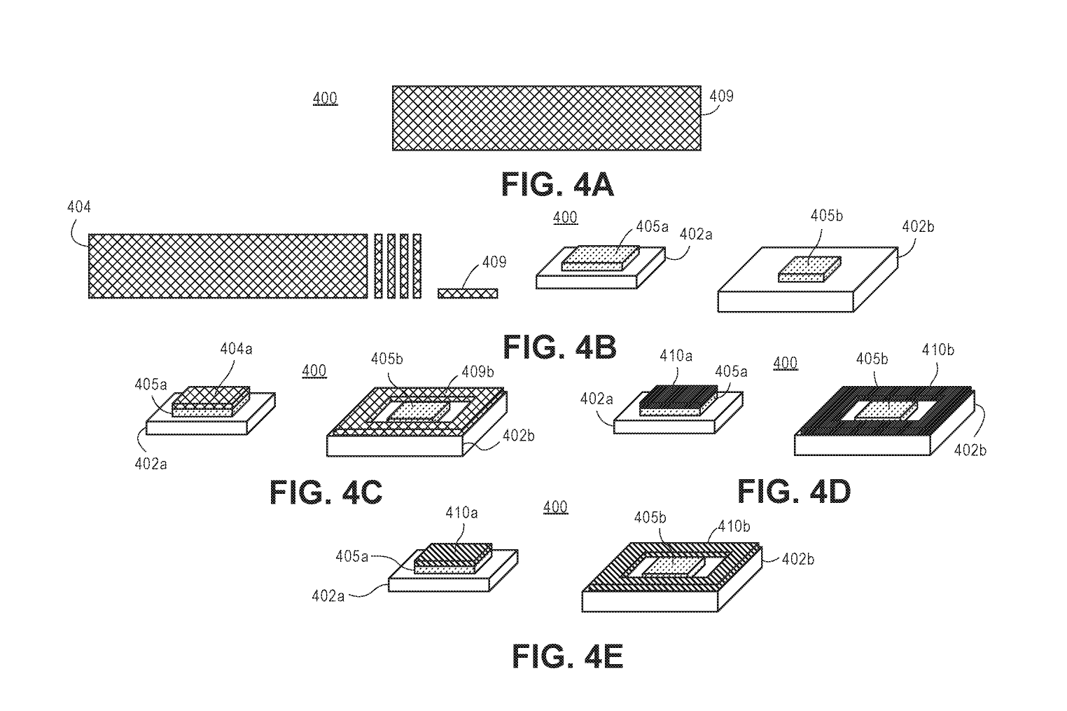

As shown below, a BCC may be disposed on a semiconductor package to form BCC stiffeners on at least one of a die and a substrate using one or more methods/process flows (e.g., using a resin pre-loaded in a ceramic, a polymeric resin dispensed in a liquid state, a wafer-level stiffener, etc.). For one embodiment, a process flow may form BCC stiffeners with polymeric resin dispensed in a liquid state (e.g., as shown in FIGS. 4A-4E). When using a polymeric resin dispensed in a liquid state technique, a porous ceramic may be pre-machined with a desired dimension and pick-and-placed on a substrate. After placing the ceramic, a liquid epoxy resin may be dispensed (or disposed) on a top surface of the porous ceramic at specific temperatures to achieve optimum viscosity so the resin may fill the entire ceramic porous matrix and wet to the substrate. In this process, the capillary forces within the ceramic matrix allow a simple dispense process to fill the porous ceramic. Additionally, for a controlled dispense weight, the capillary forces may retain the resin within the ceramic and thus control the keep-out-zones (KOZs) to avoid overflow. After dispensing the resin, the entire package is subjected to curing conditions to allow the resin to cure.

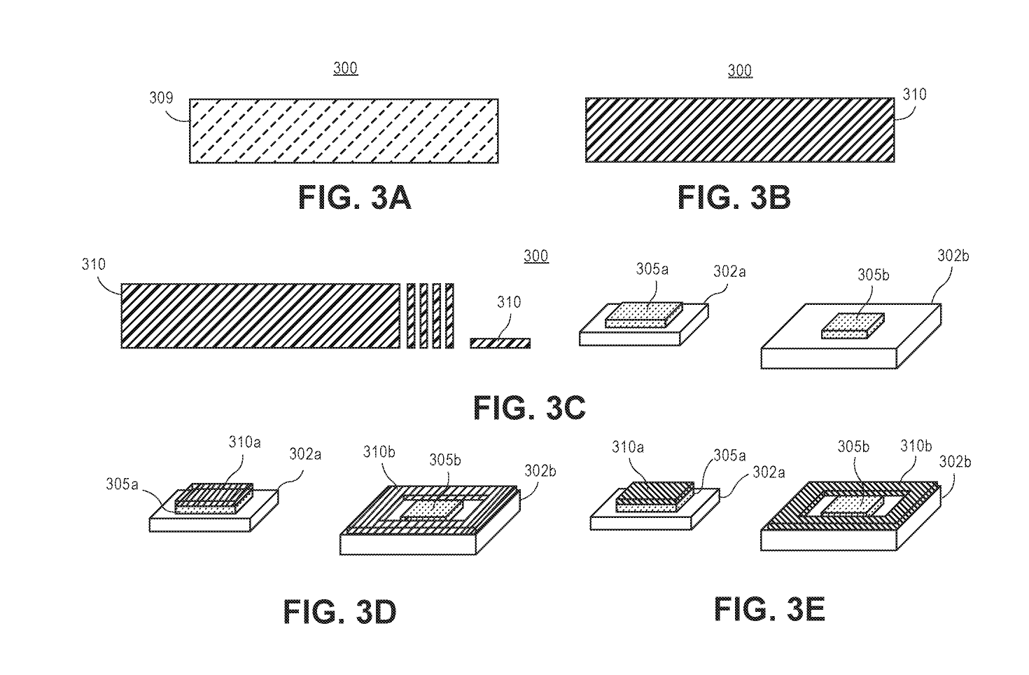

For another embodiment, a process flow may form BCC stiffeners with resin pre-loaded in a ceramic (e.g., as shown in FIGS. 3A-4E). When using a resin pre-loaded in a ceramic, polymer resins may be selected based on one or more properties. The selected polymer resins may need to be solid at room temperature, but also soften and flow at higher temperatures. For example, one of these polymer resins may be a b-stage polymerized epoxy resin that is used for epoxy mold compounds. Additionally, prior to a pick-and-place step, a pre-machined porous ceramic may be impregnated with the resin beforehand (i.e., pre-loaded in the ceramic), and then the resin pre-loaded in the ceramic is cooled to room temperature as the resin is solidified (or has a solid-like property). The resin pre-loaded (or soaked) in the ceramic can then be pick-and-placed on a substrate. After placing the ceramic, the substrate can be subjected to a thermal profile where the resin can soften and form a bond between the ceramic matrix and the substrate. Note that the resin pre-loaded in the ceramic method improves semiconductor packaging solutions by simplifying the application process for warpage control and package stiffness (e.g., this method may significantly simply the application process over epoxy mold compounds and stainless steel stiffeners that are typically used).

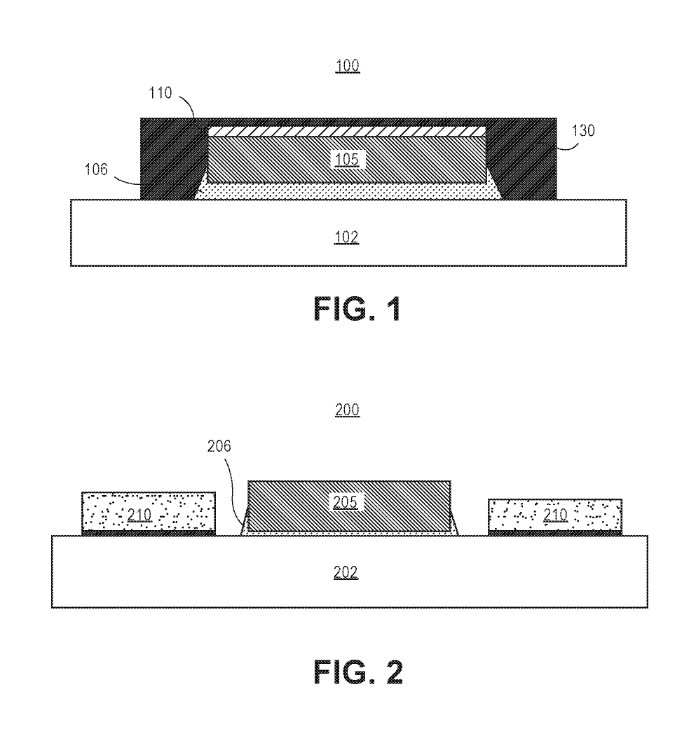

As shown below in FIGS. 1-2, the BCC may be disposed on a backside of a die and/or around a die to perform as stiffeners for mitigating warpage. Specifically, embodiments of a semiconductor package including a BCC die backside stiffener and/or a BCC picture frame stiffener using the one or more process flows are described in further detail below. These embodiments further help to overcome the limitations on (i) the expansion of the die-to-package area ratio (in the x-y plane) by reducing the area ratio with the stiffener disposed directly on the backside of the die; and (ii) the miniaturization of packages by reducing the overall z-height of the package with the stiffener disposed directly on the backside of the die without any additional adhesive layer in between. The embodiments of the BCC, therefore, help to improve package stiffness, warpage control, and thermal management on packages without increasing the z-height, cost, and total number of manufacturing steps.

FIG. 1 is a cross-sectional view of a semiconductor package 100 with a BCC die backside stiffener 110, a die 105, and a substrate 106, according to one embodiment. For one embodiment, the BCC die backside stiffener 110 can be disposed directly on the die 105 at a unit level as a singulated stiffener on the backside of the die 105. For an alternative embodiment, the BCC die backside stiffener 110 can be disposed directly on the die 105 at the wafer level as a die/stiffener stacked wafer that can then be singulated and placed into tape and reel prior to the die attach.

As used herein, a “stiffener” (or a BCC stiffener) refers to using one or more BCC materials to act as a stiffening structure/layer on a backside of a die (i.e., a die backside stiffener) and/or to surround a die (i.e., a picture frame stiffener) for mitigating warpage on a package (or substrate). As described above, a “stiffener” may be formed using one or more BCC materials that include polymer resins, ceramics, and metals. As used herein, a “z-height” refers to a unit of measurement on the z-axis in a three-dimensional package, which is usually oriented vertically.

Referring now to FIG. 1, the die 105 is disposed on the substrate 102. For one embodiment, the die 105 has a front side surface that is electrically coupled to the substrate 102 via the underfill layer 106 which is understood to also include first level interconnects (FLI) such as solder bumps. According to some embodiments, the die 105 has a backside surface (also referred to as the backside) directly coupled with the BCC stiffener 110. The BCC stiffener 110 may be disposed on the backside of the die 105 without requiring an additional adhesive layer (e.g., an epoxy film, an attachment film, etc.) to attach the backside of the die 105 and the BCC stiffener 110.

For some embodiments, the BCC stiffener 110 helps reduce package warpage by creating the BCC structure/layer on the die 105 to counteract the CTE mismatch between the die 105 and the substrate 102. The BCC stiffener 110 thus strengthens the mechanical coupling between the die 105 and the BCC stiffener 110, which enables the BCC stiffener 110 to provide a warpage control solution for the semiconductor package 100.

For one embodiment, the die 105 may include, but is not limited to, a semiconductor die, an integrated circuit, a central processing unit (CPU), a microprocessor, a platform controller hub (PCH), a memory, and a field programmable gate array (FPGA). In addition, for other embodiments, the semiconductor package 100 may include multiple dies (not shown) that need BCC stiffeners. The BCC stiffener 110 (also referred to as a BCC stiffener structure or a BCC stiffening layer) is formed/disposed directly on the backside of the die 105 to mitigate warpage both room temperatures and reflow temperatures. According to some embodiments, the BCC stiffener 110 may be formed as a bicontinuous composite of a porous ceramic and curable polymeric resin. The BCC stiffener 110 provides a connected rigid matrix with a decreased CTE, a durable bending stiffness, and an improved bond/adhesion on the die 105 (and/or any other silicon device or organic substrate). Note that, as shown below in the process flows of FIGS. 3-4 and 6, the BCC stiffener 110 may be formed using one or more techniques such as a resin pre-loaded in a ceramic, a polymeric resin in a liquid state, and/or a wafer-level stiffener.

In one embodiment, the underfill layer 106 is formed between the die 105 and the substrate 102. For additional embodiments, the substrate 102 may be disposed on a motherboard (not shown) or any other packaging substrate, where the substrate 102 may be electrically coupled to the motherboard using solder bumps (not shown).

According to one embodiment, the substrate 102 may include, but is not limited to, a package, a packing substrate, a printed circuit board (PCB), a high-density interconnect (HDI) board, a ceramic substrate, or any organic semiconductor packaging substrate. For one embodiment, the substrate 102 is a PCB. For one embodiment, the PCB is made of an FR-4 glass epoxy base with thin copper foil laminated on both sides (not shown). For certain embodiments, a multilayer PCB can be used, with pre-preg and copper foil (not shown) used to make additional layers. For example, the multilayer PCB may include one or more dielectric layers, where each dielectric layer can be a photosensitive dielectric layer (not shown). For some embodiments, the PCB may have holes (not shown) drilled in the PCB, and the PCB may also include conductive copper traces, metallic pads, and holes (not shown).

The substrate 102 may be electrically coupled to the die 105 via the underfill layer 106, which may include solder balls/bumps (not shown) that connect pads (not shown) on the substrate 102 and the die 105. For example, the underfill layer 106 may be used on a ball grid array (BGA), a pin grid array (PGA), a land grid array (LGA), or any other connectivity packaging. For one embodiment, the underfill layer 106 may include controlled collapse chip connection (C4) bumps that connect pads (not shown) on the die 105 and the substrate 102.

In some optional embodiments, a mold layer 130 (or an encapsulation layer) may be disposed over and around the BCC stiffener 110, the die 105, the underfill layer 106, and the substrate 102. The mold layer 130 can be used to protect the semiconductor package 100 from the environment. For one embodiment, the mold layer 130 may be cured after the deposition (or overmolding). Note that the mold layer 130 may help to protect and cover the semiconductor package 100 from humidity, photons, corrosion and damage.

For one embodiment, the mold layer 130 may include an epoxy (e.g., a soft epoxy, a stiff epoxy, opaque epoxy, etc.) with one or more filler materials. For some embodiments, the mold layer 130 may be formed with one or more encapsulant materials that are dispensed onto the semiconductor package 100 rather than using injection, compression, or transfer mold processes. Note that, as shown in FIG. 1, the mold layer 130 may be a rectangular enclosure but may also have any arbitrary shape/texture, including hemispherical shape, a capsule-like shape, a honeycombed shape, a round shape, one or more dimples to fit in certain devices, etc.

As illustrated in FIG. 1, the absence of an adhesive layer (or an epoxy film) on the backside of the die 105 facilitates a direct bond formed between the BCC stiffener 110 and the die 105 to have strong coupling at high temperatures. In addition to controlling package warpage, the BCC stiffener 110 may also provide thermal management for the semiconductor package 100. For example, the BCC stiffener 110 may include a thermally conductive porous ceramic/metal that forms a continuous thermal path to help spread the heat from the die 105 to the environment above the BCC stiffener 110.

The BCC stiffener 110 may be optimized/tuned based on the selected final properties of the BCC (e.g., based on the pore size, the smaller pores lead to lower CTE). Additionally, the BCC 110 may include a porous ceramic that can be easily modified in terms of the porosity and pore size to allow a polymeric resin to flow through it (where the capillary forces within the porous ceramic may drive/control the resin flow). Further, the polymeric resin viscosity of the BCC stiffener 110 can be tailored for better filling and then the resin can be subjected to cure at high temperature. Moreover, the BCC stiffener 110 helps to (i) reduce the overall assembly (e.g., by using the pick-and-place process described herein) and (ii) improve the yield of thin packages, such as mobile products (or smartphones), tablets, and wearables.

Note that the semiconductor package 100 may include fewer or additional packaging components based on the desired packaging design.

FIG. 2 is a cross-sectional view of a semiconductor package 200 with a BCC picture frame stiffener 210, a die 205, and a substrate 202, according to one embodiment. The waveguide semiconductor package 200 may be similar to the semiconductor package 100 of FIG. 1, but the semiconductor package 200 uses a BCC to form the picture frame stiffener 210 around/surrounding the die 205. Additionally, the BCC stiffener 210 may be disposed on the substrate 202 pre or post die attach.

As shown in FIG. 2, the semiconductor package 200 has the die 205 disposed on the substrate 202. For one embodiment, the die 205 has a front side surface that is electrically coupled to the substrate 202 via the underfill layer 206. According to some embodiments, the BCC stiffener 210 is formed to surround (or be adjacent to) the die 205, and the BCC stiffener 210 is directly disposed on the top surface of the substrate 202 without needing an additional adhesive layer (e.g., an epoxy film) to bond/attach the BCC stiffener 210 and the substrate 202. For example, the BCC stiffener 210 is disposed on the substrate 202 and has a polymeric resin 210 impregnate through the porous ceramic down to the surface of the substrate 202 to form a bond between the top surface of the substrate 202 and the BCC stiffener 210.

For one embodiment, the BCC stiffener 210 is formed directly on the top surface of the substrate 202 to mitigate warpage (i.e., the package warpage of semiconductor package 200) generated by the CTE mismatch between the die 205 and the substrate 202. As noted above, thin packages (e.g., such as substrate 202) are susceptible to the problem of deformation (or warping) due to temperature cycling between lower temperatures (e.g., room temperature) and higher temperatures (e.g., those required for mass reflow of solder bumps). Accordingly, as the embodiments described herein, the final properties selected for the formation of the BCC, which is implemented as a stiffener (e.g., BCC stiffener 210), may facilitate a warpage control solution for the thin package (e.g., substrate 202) at both room and reflow temperatures to overcome the problem above.

For example, the BCC stiffener 210 may increase the stiffness of the substrate 202 and reduce the warpage that is caused by the reflow process. Furthermore, the BCC stiffener 210 may reduce the difficulty of handling a thin and flexible substrate 202 as the BCC stiffener 210 provides rigidity to the otherwise flexible substrate 202. For example, the BCC stiffener 210 may enable for the substrate 202 to be handled and processed without specialized handling equipment that may be typically needed for such thin and flexible substrates.

For some embodiments, as described above, the BCC stiffener 210 may include one or more bicontinuous composite materials, including, but not limited to, polymeric resins, porous ceramics, and/or metals. For one embodiment, the one or more materials selected for the BCC stiffener 210 may be selected in order to optimize the effective CTE and modulus for producing minimal package warpage for the semiconductor package 200.

Note that the semiconductor package 200 may include fewer or additional packaging components based on the desired packaging design.

FIGS. 3A-3E are perspective view illustrations of a method 300 of forming BCC stiffeners 310a-b on a die 305a and/or a substrate 302b using a resin pre-loaded in a ceramic, according to some embodiments. Specifically, FIGS. 3A-3E illustrate a process flow 300 of forming a BCC die backside stiffener 310a and a BCC picture frame stiffener 310b using the resin pre-loaded in ceramic method (i.e., a pre-fill, cut, and place embodiment). For example, process flow 300 shows a method of forming the BCC stiffeners as shown in FIGS. 1-2. Note that, in FIGS. 3C-3E, some of the components are referenced with an “a” (e.g., 305a) and/or a “b” (e.g., 305b) to differentiate the process flow used for the applications of a die backside stiffener (illustrated with “a” components) and a picture frame stiffener (illustrated with “b” components). Also note that FIGS. 3A-3E illustrates the process flow 300 implementing both BCC stiffeners 310a-b in parallel, however the process flow 300 can be used for the formation of one BCC stiffener (as this process flow is shown for clarity, simplification, and to avoid confusion).

At FIG. 3A, the process flow 300 includes a porous ceramic layer 309 that may be selected based on the one or more different types of porous ceramics and the pore size and density of the ceramics. At FIG. 3B, the process flow 300 disposes a polymeric resin on the porous ceramic layer to impregnate the porous ceramic layer, thus forming a pre-machined (or pre-loaded) BCC layer 310 in advance (or prior) to a pick-and-place step (as shown in FIG. 3D). For one embodiment, the BCC layer 310 is filled (or dispensed, vacuum infusioned, etc.) with the polymeric resin, and then the BCC layer 310 of FIG. 3B (i.e., the polymeric resin pre-loaded in the ceramic) is partially cured by cooling the BCC layer 310 to room temperature as the polymeric resin is solidified (or has a solid-like property). Note that, as described above, the polymer resin may be selected based on one or more properties, for example, the selected polymer resins may need to be solid at room temperature, but also soften and flow at higher temperatures.

At FIG. 3C, the process flow 300 cuts the BCC layer 310 into one or more shapes (or smaller layers/units), where each of the cut shapes of the BCC layer 310 may be patterned/formed as a die backside stiffener and/or a picture frame stiffener. Furthermore, as shown in FIG. 3C, the process flow 300 disposes dies 305a-b on substrates 302a-b, respectively, where the substrate 302b may have a larger surface area for the placement of a picture frame stiffener. At FIG. 3D, the process flow 300 picks-and-places a BCC die backside stiffener 310a on the die 305a and a BCC picture frame stiffener 310b on the substrate 302b surrounding the die 305b. At FIG. 3E, the process flow 300 implements a reflow on the stiffeners 310a-b on the die 302a and the substrate 302b, respectively. For example, the substrates 302a-b can be subjected to a thermal profile where the polymeric resin can soften and form a bond between the BCC stiffener 310a and the die 304a and/or the BCC stiffener 310b and the substrate 302b. For some embodiments, the process flow 300 implements a polymeric resin pre-loaded in a ceramic which improves semiconductor packaging solutions by simplifying the application process for warpage control and package stiffness (e.g., this process flow may significantly simply the application process over epoxy mold compounds and stainless steel stiffeners that are typically used on packages).

Note that the process flow as shown in FIGS. 3A-3E may include fewer or additional packaging components based on the desired packaging design.

FIGS. 4A-4E are perspective view illustrations of a method 400 of forming BCC stiffeners 410a-b on a die 405a and/or a substrate 402b using a polymeric resin in a liquid state, according to some embodiments. Specifically, FIGS. 4A-4E illustrate a process flow 400 of forming a BCC die backside stiffener 410a and a BCC picture frame stiffener 410b using the polymeric resin in the liquid state method (i.e., a cut, place, and dispense embodiment). For example, process flow 400 shows a method of forming the BCC stiffeners as shown in FIGS. 1-2. Note that, in FIGS. 4B-4E, some of the components are referenced with an “a” (e.g., 405a) and/or a “b” (e.g., 405b) to differentiate the process flow used for the applications of a die backside stiffener (illustrated with “a” components) and a picture frame stiffener (illustrated with “b” components). Also note that FIGS. 4A-4E illustrates the process flow 400 implementing both BCC stiffeners 410a-b in parallel, however the process flow 400 can be used for the formation of one BCC stiffener (as this process flow is shown for clarity, simplification, and to avoid confusion).

At FIG. 4A, the process flow 400 includes a porous ceramic layer 409 that may be selected based on the one or more different types of porous ceramics and the pore size and density of the ceramics. At FIG. 4B, the process flow 400 cuts the porous ceramic layer 409 into one or more shapes (or smaller layers/units), where each of the cut shapes of the porous ceramic layer 409 may be patterned/formed as a die backside stiffener and/or a picture frame stiffener. Furthermore, as shown in FIG. 4B, the process flow 400 disposes dies 405a-b on substrates 402a-b, respectively, where the substrate 402b may have a larger surface area for the placement of a picture frame stiffener. As such, the process flow 400 of FIGS. 4A-4B illustrates the porous ceramic layer 409 pre-machined with a desired dimension (i.e., cutting the layer 409 into smaller desired shapes), and then theses shapes are picked-and-placed on a die and/or a substrate (as shown in FIG. 4C).

At FIG. 4C, the process flow 400 picks-and-places a BCC die backside stiffener 410a on the die 405a and a BCC picture frame stiffener 410b on the substrate 402b surrounding the die 405b. Note that, during the process flow 400 illustrated in FIG. 4C, the BCC stiffeners 410a-b are shaped structures formed/patterned with the porous ceramic layer 409 (i.e., the BCC stiffeners 410a-b of FIG. 4C may be porous ceramic matrixes/layers prior to being dispensed with the polymeric resin).

At FIG. 4D, the process flow 400 disposes a polymeric resin on the porous ceramic layers (of the stiffeners 410a-b) to impregnate the porous ceramic layers, thus forming the BCC stiffeners 410a-b. Note that, as described above, the polymer resin may be selected based on one or more properties, for example, the selected polymer resins may be dispensed (or disposed) on a top surface of the porous ceramic layers (forming the stiffeners 410a-b) at specific temperatures to achieve optimum viscosity so the resin may fill the entire ceramic porous matrix and wet to the die 405a and/or the substrate 402b. During the process flow 400 at FIG. 4D, the capillary forces within the ceramic matrix may allow a simple dispense process to fill the porous ceramic. Additionally, for a controlled dispense weight, the capillary forces may retain the resin within the ceramic and thus control the keep-out-zones (KOZs) to avoid overflow on the substrates 402a-b.

At FIG. 4E, the process flow 400 implements a reflow on the stiffeners 410a-b on the die 402a and the substrate 402b, respectively. After dispensing the resin, the substrates 402a-b are subjected to curing conditions to allow the resin to cure. For example, the substrates 402a-b can be subjected to a thermal profile where the polymeric resin can soften and form a bond between the BCC stiffener 410a and the die 404a and/or the BCC stiffener 410b and the substrate 402b.

Note that the process flow as shown in FIGS. 4A-4E may include fewer or additional packaging components based on the desired packaging design.

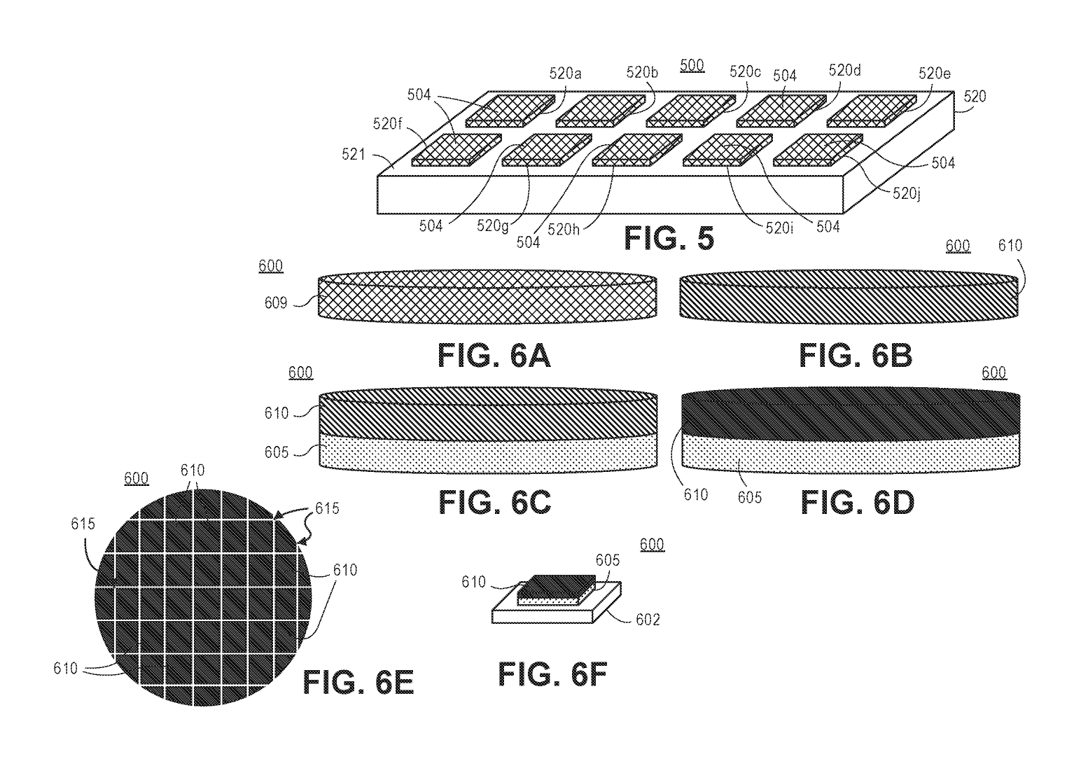

FIG. 5 is a perspective view of a stiffener system 500 including a tray 520 with a top surface 521 that has one or more shaped-openings 520a-j used to form one or more BCC die backside stiffeners, according to one embodiment. For one embodiment, a porous ceramic 504 is selected and then disposed on the one or more openings 520a-j of the tray 520 to form the die backside stiffeners, which may have pre-formed (or pre-patterned) shapes that are sintered in the tray 520. Accordingly, the one or more BCC shapes/stiffeners 504 may be stripped at a strip level and then disposed on a respective die and/or substrate. Note that the stiffener system 500 may include fewer or additional packaging components based on the desired packaging design.

FIGS. 6A-6F are perspective view illustrations of a process flow 600 of forming a BCC die backside stiffener 610 on a wafer level, according to some embodiments. For example, FIG. 6E illustrates a plan view of a wafer diced into dies 605 and BCC die backside stiffeners 610. In addition, the process flow 600 of FIGS. 6A-6F shows the deposition of a BCC stiffener layer 610 at a wafer level using, for example, the resin pre-loaded in ceramic method as described above. For one embodiment, the process flow 400 shows a method of forming the BCC die backside stiffener as shown in FIG. 1.

At FIG. 6A, the process flow 600 includes a porous ceramic layer 609 that may be selected based on the one or more different types of porous ceramics and the pore size and density of the ceramics. At FIG. 6B, the process flow 600 disposes a polymeric resin on the porous ceramic layer 609 to impregnate the porous ceramic layer, thus forming a pre-machined (or pre-loaded) BCC layer 610 in advance (or prior) to stiffener attach at wafer prep steps (as shown in FIGS. 6C-6D). For one embodiment, the BCC layer 610 is filled (or dispensed, vacuum infusioned, etc.) with the polymeric resin, and then the BCC layer 610 of FIG. 6B (i.e., the polymeric resin pre-loaded in the ceramic) is partially cured by cooling the BCC layer 610 to room temperature as the polymeric resin is solidified (or has a solid-like property). Note that, as described above, the polymer resin may be selected based on one or more properties, for example, the selected polymer resins may need to be solid at room temperature, but also soften and flow at higher temperatures.

At FIG. 6C, the process flow 600 attaches the BCC layer 610 on a wafer 605. At block 6D, the process flow 600 implements a reflow on the BCC layer 610 on the wafer 605 for the stiffener attach/bond. For example, the BCC layer 610 and the wafer 605 can be subjected to a thermal profile where the polymeric resin can soften and form a bond between the BCC layer 610 and the top surface of the wafer 605. At FIG. 6E, the process flow 600 dices the BCC layer 610 on the wafer 605 forming dicing streets 615 that pattern the wafer into a plurality of singulated units, which may include a singulated BCC die backside stiffener 610 on a die 605. At FIG. 6F, the process flow 300 picks-and-places a singulated BCC die backside stiffener 610 on the die 605 onto a substrate 602. Additionally the process flow 600 may implement a thermal compression bond (TCB) and a reflow on the package to finalize the bonding of the package, which includes the stacked BCC die backside stiffener 610 and the die 605 disposed on the substrate 602.

Note that the process flow 600 as shown in FIGS. 6A-6F may include fewer or additional packaging components based on the desired packaging design.

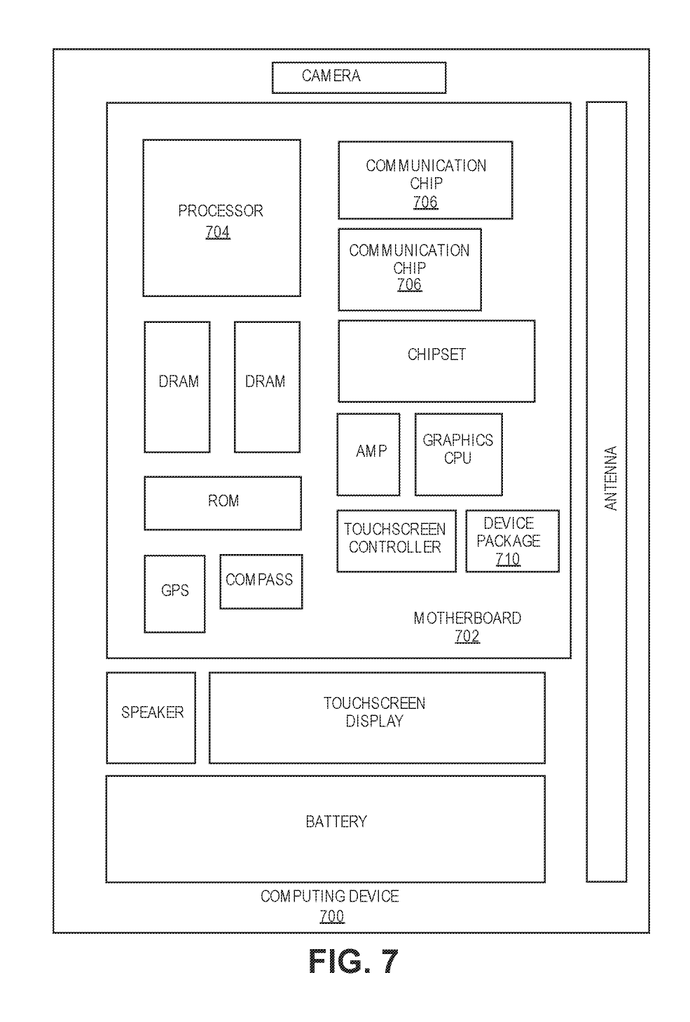

FIG. 7 is a schematic block diagram illustrating a computer system 700 that utilizes a device package 710 (or a semiconductor package) with one or more BCC stiffeners, according to one embodiment. FIG. 7 illustrates an example of computing device 700. Computing device 700 houses motherboard 702. For one embodiment, motherboard 702 may be similar to the substrates of Figures of 1-4 and 6 (e.g., packages 102, 202, 302, 402, and 602 of FIGS. 1-4 and 6). Motherboard 702 may include a number of components, including but not limited to processor 704, device package 710 (or the BCC semiconductor package/system), and at least one communication chip 706. Processor 704 is physically and electrically coupled to motherboard 702. For some embodiments, at least one communication chip 706 is also physically and electrically coupled to motherboard 702. For other embodiments, at least one communication chip 706 is part of processor 704.

Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 706 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

Processor 704 of computing device 700 includes an integrated circuit die packaged within processor 704. Device package 710 may be, but is not limited to, a packaging substrate, a PCB, and a motherboard. Device package 710 has a waveguide launcher system with a packaging having a microstrip feedline and one or more conductive layers, and a waveguide connector having a slot-line signal converter, one or more balun structures, and one or more tapered slot launchers, and the like—or any other components from the figures described herein—of the computing device 700. Device package 710 includes a waveguide launcher system that has a power-competitive solution that can support very high data rates, e.g., over short to medium distances, which would be extremely advantageous for interconnects within server and HPC architectures and/or autonomous/self-driving vehicles, according to some embodiments. Furthermore, device package 710 includes tapered-slot launchers and connectors for exciting the waveguides which facilitates an improvement in the manufacturing and assembly of waveguide interconnect systems. Device package 710 provides a tapered-slot waveguide launcher and connector enabling a wider bandwidth for thin package substrates as the demand for miniaturization persistently increases, and a decreased sensitivity to waveguide alignment and electrical contacts.

Note that device package 710 may be a single component/device, a subset of components, and/or an entire system, as the materials, features, and components may be limited to device package 710 and/or any other component that needs a waveguide launcher system.

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 706 also includes an integrated circuit die packaged within the communication chip 706. For some embodiments, the integrated circuit die of the communication chip may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1 is a device package, comprising a die on a substrate. The die has a front side surface that is electrically coupled to the substrate and a back side surface that is opposite from the front side surface; and a bicontinuous ceramic composite (BCC) stiffener on the back side surface of the die.

In example 2, the subject matter of example 1 can optionally include the BCC stiffener is formed with one or more materials. The one or more materials include porous ceramics, polymeric resins, and metals.

In example 3, the subject matter of any of examples 1-2 can optionally include the BCC stiffener directly coupled to the back side surface of the die without an adhesive layer.

In example 4, the subject matter of any of examples 1-3 can optionally include the die electrically coupled to the substrate with an underfill layer.

In example 5, the subject matter of any of examples 1-4 can optionally include the BCC stiffener is disposed on the die to reduce warpage based on the substrate and the die.

In example 6, the subject matter of any of examples 1-5 can optionally include a mold layer disposed over and around the BCC stiffener, the die, the underfill layer, and the substrate; and a motherboard disposed below the substrate. The motherboard is electrically coupled to the substrate.

In example 7, the subject matter of any of examples 1-6 can optionally include the BCC stiffener formed with the one or more materials using at least one of a polymeric resin in a liquid state process and a resin pre-loaded in a ceramic process.

In example 8, the subject matter of any of examples 1-7 can optionally include the BCC stiffener disposed on the die at a unit level or a wafer level.

Example 9 is a method of forming a device package, the method comprising disposing a die on a substrate. The die has a front side surface that is electrically coupled to the substrate and a back side surface that is opposite from the front side surface; and disposing a BCC stiffener on the back side surface of the die.

In example 10, the subject matter of example 9 can optionally include the BCC stiffener formed with one or more materials. The one or more materials include porous ceramics, polymeric resins, and metals.

In example 11, the subject matter of any of examples 9-10 can optionally include the BCC stiffener directly coupled to the back side surface of the die without an adhesive layer.

In example 12, the subject matter of any of examples 9-11 can optionally include the die electrically coupled to the substrate with an underfill layer. The BCC stiffener is disposed on the die to reduce warpage based on the substrate and the die.

In example 13, the subject matter of any of examples 9-12 can optionally include disposing a mold layer over and around the BCC stiffener, the die, the underfill layer, and the substrate; and a motherboard disposed below the substrate. The motherboard is electrically coupled to the substrate.

In example 14, the subject matter of any of examples 9-13 can optionally include the BCC stiffener formed with the one or more materials using at least one of a polymeric resin in a liquid state process and a resin pre-loaded in a ceramic process. The BCC stiffener is disposed on the die at a unit level or a wafer level.

In example 15, the subject matter of any of examples 9-14 can optionally include the resin pre-loaded in the ceramic process, further comprises disposing a polymeric resin on a porous ceramic. The polymeric resin is impregnated in the pores of the porous ceramic; cutting the porous ceramic into one or more BCC stiffeners; disposing the die on the substrate; disposing the BCC stiffener of the one or more BCC stiffeners on the die that is disposed on the substrate; and curing the BCC stiffener on the die to form a bond between a bottom surface of the BCC stiffener and the back side surface of the die.

In example 16, the subject matter of any of examples 9-15 can optionally include the polymer resin in the liquid state process, further comprises cutting a porous ceramic into one or more ceramic stiffeners; disposing the die on the substrate; disposing a ceramic stiffener of the one or more ceramic stiffeners on the die that is disposed on the substrate; dispensing a polymeric resin on the ceramic stiffener. The polymeric resin is impregnated in the pores of the ceramic stiffener to form the BCC stiffener; and curing the BCC stiffener on the die to form a bond between a bottom surface of the BCC stiffener and the back side surface of the die.

In example 17, the subject matter of any of examples 9-16 can optionally include one or more BCC stiffeners includes at least one of a BCC die backside stiffener and a BCC picture frame stiffener.

Example 18 is a device package, comprising a die on a substrate. The die has a front side surface that is electrically coupled to the substrate and a back side surface that is opposite from the front side surface; and a BCC stiffener on a top surface of the substrate. The BCC stiffener surrounds the die.

In example 19, the subject matter of example 18 can optionally include the BCC stiffener formed with one or more materials. The one or more materials include porous ceramics, polymeric resins, and metals.

In example 20, the subject matter of any of examples 18-19 can optionally include the BCC stiffener directly coupled to the top surface of the substrate without an adhesive layer.

In example 21, the subject matter of any of examples 18-20 can optionally include the die electrically coupled to the substrate with an underfill layer.

In example 22, the subject matter of any of examples 18-21 can optionally include the BCC stiffener disposed on the edges of the substrate to reduce warpage based on the substrate and the die.

In example 23, the subject matter of any of examples 18-22 can optionally include a mold layer disposed over and around the BCC stiffener, the die, the underfill layer, and the substrate; and a motherboard disposed below the substrate. The motherboard is electrically coupled to the substrate.

In example 24, the subject matter of any of examples 18-23 can optionally include the BCC stiffener formed with the one or more materials using at least one of a polymeric resin in a liquid state process and a resin pre-loaded in a ceramic process.

In example 25, the subject matter of any of examples 18-24 can optionally include the BCC stiffener disposed on the die at a unit level or a wafer level.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A device package, comprising:
a die on a substrate, wherein the die has a front side surface that is electrically coupled to the substrate and a back side surface that is opposite from the front side surface; and
a bicontinuous ceramic composite (BCC) stiffener on the back side surface of the die.

2. The device package of claim 1, wherein the BCC stiffener is formed with one or more materials, and wherein the one or more materials include porous ceramics, polymeric resins, and metals.

3. The device package of claim 1, wherein the BCC stiffener is directly coupled to the back side surface of the die without an adhesive layer.

4. The device package of claim 1, wherein the die is electrically coupled to the substrate with an underfill layer.

5. The device package of claim 1, wherein the BCC stiffener is disposed on the die to reduce warpage based on the substrate and the die.

6. The device package of claim 4, further comprising a mold layer disposed over and around the BCC stiffener, the die, the underfill layer, and the substrate; and a motherboard disposed below the substrate, wherein the motherboard is electrically coupled to the substrate.

7. The device package of claim 2, wherein the BCC stiffener is formed with the one or more materials using at least one of a polymeric resin in a liquid state process and a resin pre-loaded in a ceramic process.

8. The device package of claim 1, wherein the BCC stiffener is disposed on the die at a unit level or a wafer level.

9. A method of forming a device package, the method comprising:
disposing a die on a substrate, wherein the die has a front side surface that is electrically coupled to the substrate and a back side surface that is opposite from the front side surface; and
disposing a BCC stiffener on the back side surface of the die.

10. The method of claim 9, wherein the BCC stiffener is formed with one or more materials, and wherein the one or more materials include porous ceramics, polymeric resins, and metals.

11. The method of claim 9, wherein the BCC stiffener is directly coupled to the back side surface of the die without an adhesive layer.

12. The method of claim 9, wherein the die is electrically coupled to the substrate with an underfill layer, and wherein the BCC stiffener is disposed on the die to reduce warpage based on the substrate and the die.

13. The method of claim 12, further comprising disposing a mold layer over and around the BCC stiffener, the die, the underfill layer, and the substrate; and a motherboard disposed below the substrate, wherein the motherboard is electrically coupled to the substrate.

14. The method of claim 10, wherein the BCC stiffener is formed with the one or more materials using at least one of a polymeric resin in a liquid state process and a resin pre-loaded in a ceramic process, and wherein the BCC stiffener is disposed on the die at a unit level or a wafer level.

15. The method of claim 14, wherein the resin pre-loaded in the ceramic process, further comprises:
disposing a polymeric resin on a porous ceramic, wherein the polymeric resin is impregnated in the pores of the porous ceramic;
cutting the porous ceramic into one or more BCC stiffeners;
disposing the die on the substrate;
disposing the BCC stiffener of the one or more BCC stiffeners on the die that is disposed on the substrate; and
curing the BCC stiffener on the die to form a bond between a bottom surface of the BCC stiffener and the back side surface of the die.

16. The method of claim 14, wherein the polymer resin in the liquid state process, further comprises:
cutting a porous ceramic into one or more ceramic stiffeners;
disposing the die on the substrate;
disposing a ceramic stiffener of the one or more ceramic stiffeners on the die that is disposed on the substrate;
dispensing a polymeric resin on the ceramic stiffener, wherein the polymeric resin is impregnated in the pores of the ceramic stiffener to form the BCC stiffener; and
curing the BCC stiffener on the die to form a bond between a bottom surface of the BCC stiffener and the back side surface of the die.

17. The method of claims 15-16, wherein the one or more BCC stiffeners includes at least one of a BCC die backside stiffener and a BCC picture frame stiffener.

18. A device package, comprising:
a die on a substrate, wherein the die has a front side surface that is electrically coupled to the substrate and a back side surface that is opposite from the front side surface; and
a BCC stiffener on a top surface of the substrate, wherein the BCC stiffener surrounds the die.

19. The device package of claim 18, wherein the BCC stiffener is formed with one or more materials, and wherein the one or more materials include porous ceramics, polymeric resins, and metals.

20. The device package of claim 18, wherein the BCC stiffener is directly coupled to the top surface of the substrate without an adhesive layer.

21. The device package of claim 18, wherein the die is electrically coupled to the substrate with an underfill layer.

22. The device package of claim 18, wherein the BCC stiffener is disposed on the edges of the substrate to reduce warpage based on the substrate and the die.

23. The device package of claim 21, further comprising a mold layer disposed over and around the BCC stiffener, the die, the underfill layer, and the substrate; and a motherboard disposed below the substrate, wherein the motherboard is electrically coupled to the substrate.

24. The device package of claim 19, wherein the BCC stiffener is formed with the one or more materials using at least one of a polymeric resin in a liquid state process and a resin pre-loaded in a ceramic process.

25. The device package of claim 18, wherein the BCC stiffener is disposed on the die at a unit level or a wafer level.
